(19) United States
(12) Patent Application Publication
(10) Pub. No.: US 2025/0268007 A1
(43) Pub. Date: Aug. 21, 2025

(54) MULTI-DIE PACKAGE WITH SHAPED LUMINANCE

(71) Applicant: LUMILEDS LLC, San Jose, CA (US)

(72) Inventors: Florent MONESTIER, Eindhoven (NL); Yu-Chen SHEN, Sunnyvale, CA (US); Jeff DiMARIA, Scotts Valley, CA (US)

(73) Assignee: LUMILEDS LLC, San Jose, CA (US)

(21) Appl. No.: 19/200,954

(22) Filed: May 7, 2025

Related U.S. Application Data
(63) Continuation of application No. PCT/US2023/081906, filed on Nov. 30, 2023.
(60) Provisional application No. 63/433,279, filed on Dec. 16, 2022.

(51) Int. Cl. H10H 29/49; H10H 20/825; H10H 29/80

(52) U.S. Cl. CPC H10H 29/49; H10H 20/825; H10H 29/8321

(57) ABSTRACT

This specification discloses a light emitting devices with electrical pads improving performance. The electrical pads are disposed under the dies to prevent hot spots from occurring, particularly under the peak luminance areas of shaped luminance dies. The electrical pads may have asymmetric n and p areas, with the larger of the areas being disposed under the peak luminance area while the gap between the n and p areas do not overlap the peak luminance area. The electrical pads of different dies are bridged by horizontal or diagonal connections between the dies.

### CROSS REFERENCE TO RELATED APPLICATIONS

This application is a continuation of PCT Application PCT/US2023/081906 filed on Nov. 30, 2023, which claims benefit of priority to U.S. provisional application No. 63/433,279 filed on Dec. 16, 2022. Both of the above applications are incorporated by reference in this application in their entirety.

### FIELD OF THE INVENTION

The invention relates generally to LEDs, pcLEDs, LED and pcLED arrays, light sources comprising LEDs, pcLEDs, LED arrays, or pcLED arrays, multi-die packages comprising LED or pcLED arrays, and automotive headlamps comprising such multi-die packages.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths.

LEDs may be combined with one or more wavelength converting materials (generally referred to herein as “phosphors”) that absorb light emitted by the LED and in response emit light of a longer wavelength. For such phosphor-converted LEDs (“pcLEDs”), the fraction of the light emitted by the LED that is absorbed by the phosphors depends on the amount of phosphor material in the optical path of the light emitted by the LED, for example on the concentration of phosphor material in a phosphor layer disposed on or around the LED and the thickness of the layer. Phosphor-converted LEDs may be designed so that all the light emitted by the LED is absorbed by one or more phosphors, in which case the emission from the pcLED is entirely from the phosphors. In such cases the phosphor may be selected, for example, to emit light in a narrow spectral region that is not efficiently generated directly by an LED. Alternatively, pcLEDs may be designed so that only a portion of the light emitted by the LED is absorbed by the phosphors, in which case the emission from the pcLED is a mixture of light emitted by the LED and light emitted by the phosphors. By suitable choice of LED, phosphors, and phosphor composition, such a pcLED may be designed to emit, for example, white light having a desired color temperature and desired color-rendering properties.

Inorganic LEDs and pcLEDs have been widely used to create different types of displays, matrices and light engines including automotive adaptive headlights, augmented-reality (AR) displays, virtual-reality (VR) displays, mixed-reality (MR) displays (AR, VR, and MR systems referred to herein as visualization systems), smart glasses and displays for mobile phones, smart watches, monitors and TVs, and flash illumination for cameras in mobile phones. Individual LEDs or pcLEDs in these architectures can have an area of a few square millimeters down to a few square micrometers (e.g., microLEDs) depending on the matrix or display sized and its pixel per inch requirements.

Such LEDs and pcLEDs may be arranged in arrays for use, for example, in automotive vehicles, and for general illumination including indoor and outdoors. Specifically, certain of these LEDs and pcLEDs may be shaped to have a specific luminance profile with a luminance gradient and/or region with peak luminance. Particularly, these multi-die packages with these LEDs and pcLEDs may be useful for high and low beam applications in automotive headlights. Oftentimes these devices are subject to physical constraints to meet optical and thermal requirements, so that they illuminate efficiently while having good dissipation. Optical requirements may suggest that dies in multi-die packages be spaced as closely as possible. At the same time, manufacturing tolerances to avoid short circuit and solder overflow from connecting dies with one another may suggest spacing the die further apart. A die design that meets all of these requirements is needed.

### SUMMARY

This specification discloses ways of connecting dies to each other that provides better heat dissipation, prevents short circuiting during manufacturing, and/or increases optical efficiency for shaped luminance dies. These advantages may be derived from horizontally orienting the pads so that the gap between the opposite polarity electrical pads under the die does not overlap with the peak luminance region of the die. Further advantages may be derived from inverting the electrical pad polarity between neighboring die or diagonally connecting opposite polarity electrical pads between neighboring die.

This invention can be used in any automotive headlamps where a multi-die package is needed. It is preferably use in multi die package where surface luminance distribution of each die is intentionally not uniform and where large electrical pads have to cover fully the area where the peak current is generated to reduce thermal resistance.

Other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIG. 1 shows a schematic cross-sectional view of an example pcLED.

FIGS. 2A and 2B show, respectively, cross-sectional and top schematic views of an array of pcLEDs. FIG. 2C shows a schematic top view of an LED wafer from which LED arrays such as those illustrated in FIGS. 2A and 2B may be formed.

FIG. 3A shows a schematic top view of an electronics board on which an array of LEDs or pcLEDs may be mounted, and FIG. 3B similarly shows an array of pcLEDs mounted on the electronic board of FIG. 3A.

FIG. 4A shows a schematic cross-sectional view of an array of pcLEDs arranged with respect to waveguides and a projection lens. FIG. 4B shows an arrangement similar to that of FIG. 4A, without the waveguides.

FIG. 5 schematically illustrates an example camera flash system.

FIG. 6 shows a top view of a multi-die package with dies of shaped luminance.

FIG. 7 shows a top view of a die and electrical pads under the die that are vertically oriented.

FIG. 8 shows a top view of a die and under electrical pads under the die that are horizontally oriented so that the gap between the n and p regions do not overlap with the peak luminance area of the die.

FIG. 9a illustrates a top view of a multi-die package with dies of shaped luminance and electrical pads that are horizontally aligned with pads of neighboring dies of the same polarity. FIG. 9b illustrates the same view making visible the tile top metallization layers of the electrical pad and diagonal connections connecting the metallization layers of the electrical pads.

FIG. 10 illustrates a cross section of the multi-die package viewed from a lower edge of the package.

FIG. 11 illustrates a cross section of the multi-die package viewed from a side edge of the package.

FIG. 12 illustrates metallization layers of electrical pads with the diagonal connections.

FIG. 13 illustrates a top view of a multi-die package with dies of shaped luminance and electrical pads that are horizontally aligned with pads of neighboring dies of the opposite polarity, with visible tile top metallization layers bridged by horizontal connections.

FIG. 14 illustrates metallization layers of electrical pads with horizontal connections.

FIG. 15 illustrates a cross section of the multi-die package viewed from a lower edge of the package.

FIG. 16 illustrates dies and metallization layers of electrical pads with horizontal connections in a 1×5 array.

FIG. 17 illustrates metallization layers of electrical pads with horizontal connections in a 1×5 array.

FIG. 18 illustrates a cross section of the under bump metallization layers of the electrical pads and the layers that form their electrical connections to the die.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention.

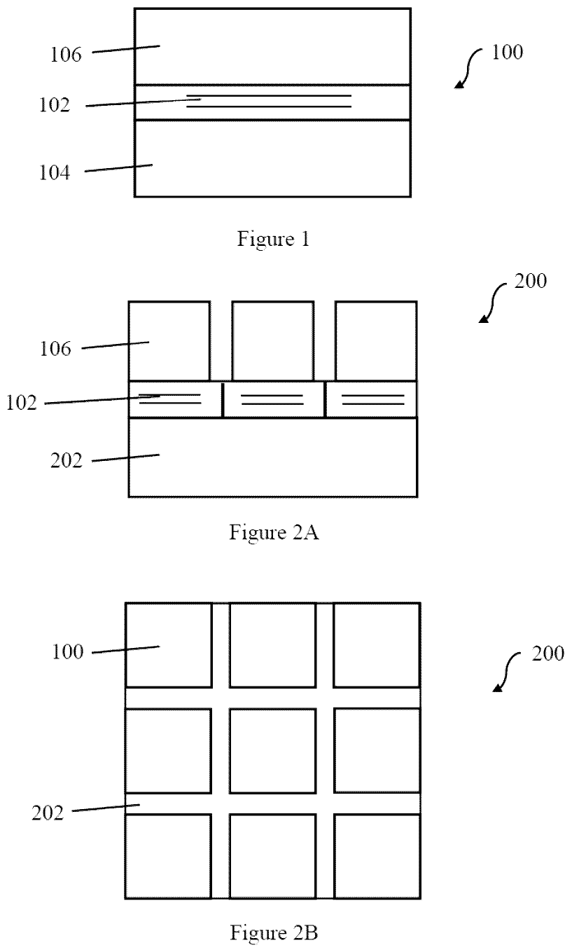

FIG. 1 shows an example of an individual pcLED 100 comprising a light emitting semiconductor diode (LED) structure 102 disposed on a substrate 104, and a phosphor layer 106 (which may also be referred to herein as a wavelength converting structure) disposed on the LED. Light emitting semiconductor diode structure 102 typically comprises an active region disposed between n-type and p-type layers. Application of a suitable forward bias across the diode structure results in emission of light from the active region. The wavelength of the emitted light is determined by the composition and structure of the active region.

The LED may be, for example, a III-Nitride LED that emits ultraviolet, blue, green, or red light. LEDs formed from any other suitable material system and that emit any other suitable wavelength of light may also be used. Other suitable material systems may include, for example, III-Phosphide materials, III-Arsenide materials, and II-VI materials.

Any suitable phosphor materials may be used, depending on the desired optical output and color specifications from the pcLED. Phosphor layers may for example comprise phosphor particles dispersed in or bound to each other with a binder material or be or comprise a sintered ceramic phosphor plate.

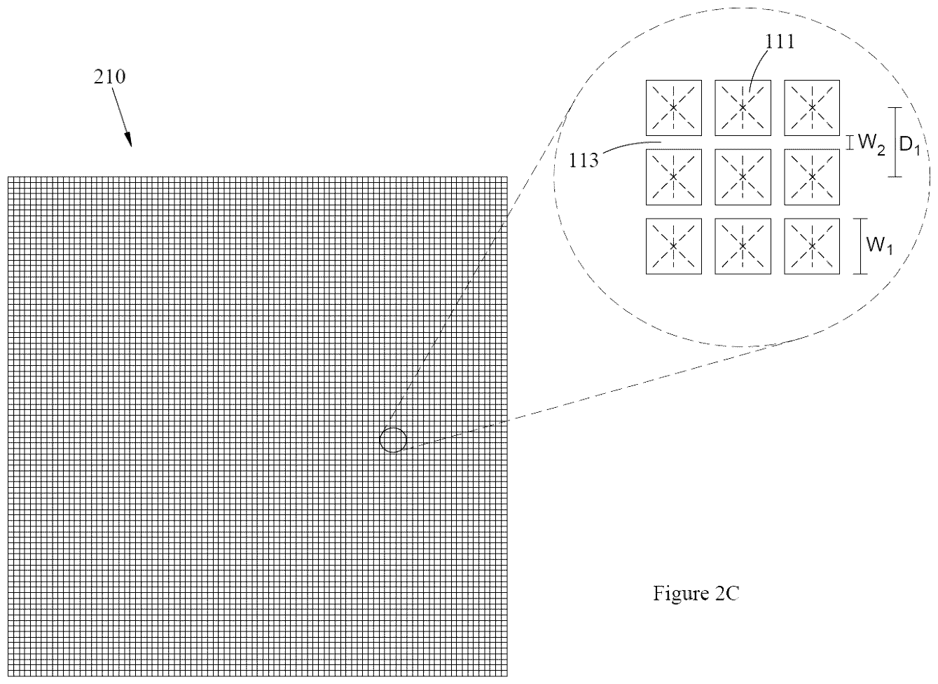

FIGS. 2A-2B show, respectively, cross-sectional and top views of an array 200 of pcLEDs 100 including phosphor layers 106 disposed on a substrate 202. Such an array may include any suitable number of pcLEDs arranged in any suitable manner. In the illustrated example the array is depicted as formed monolithically on a shared substrate, but alternatively an array of LEDs or pcLEDs may be formed from individual mechanically separate LEDs or pcLEDs. Substrate 202 may optionally comprise CMOS circuitry for driving the LEDs and may be formed from any suitable materials.

Although FIGS. 2A-2B show a three-by-three array of nine pcLEDs, such arrays may include for example tens, hundreds, or thousands of LEDs or pcLEDs. Individual LEDs or pcLEDs may have widths (e.g., side lengths) in the plane of the array of, for example, less than or equal to 1 millimeter (mm), less than or equal to 500 microns, less than or equal to 100 microns, less than or equal to 50 microns, or less than or equal to 10 microns. LEDs in such an array may be spaced apart from each other by streets or lanes having a width in the plane of the array of, for example, hundreds of microns, less than or equal to 100 microns, less than or equal to 50 microns, less than or equal to 10 microns, or less than or equal to 5 microns. Although the illustrated examples show rectangular LEDs or pcLEDs arranged in a symmetric matrix, the LEDs or pcLEDs and the array may have any suitable shape or arrangement and need not all be of the same shape or size. For example, LEDs or pcLEDs located in central portions of an array may be larger than those located in peripheral portions of the array. Alternatively, LEDs or pcLEDs located in central portions of an array may be smaller than those located in peripheral portions of the array.

FIG. 2C shows a schematic top view of a portion of an LED wafer 210 from which LED arrays such as those illustrated in FIGS. 2A and 2B may be formed. FIG. 2C also shows an enlarged 3×3 portion of the wafer. In the example wafer individual LEDs or pcLEDs 111 having side lengths (e.g., widths) of W1 are arranged as a square matrix with neighboring LEDs or pcLEDs having a center-to-center distances D1 and separated by lanes 113 having a width W2. W1 may be, for example, less than or equal to 1 millimeter (mm), less than or equal to 500 microns, less than or equal to 100 microns, less than or equal to 50 microns, or less than or equal to 10 microns. W2 may be, for example, hundreds of microns, less than or equal to 100 microns, less than or equal to 50 microns, less than or equal to 10 microns, or less than or equal to 5 microns. D1=W1+W2.

An array may be formed, for example, by dicing wafer 210 into individual LEDs or pcLEDs and arranging the dice on a substrate. Alternatively, an array may be formed from the entire wafer 210, or by dividing wafer 210 into smaller arrays of LEDs or pcLEDs.

LEDs or pcLEDs having dimensions in the plane of the array (e.g., side lengths) of less than or equal to about 50 microns are typically referred to as microLEDs, and an array of such microLEDs may be referred to as a microLED array.

In an array of pcLEDs, all pcLEDs may be configured to emit essentially the same spectrum of light. Alternatively, a pcLED array may be a multicolor array in which different pcLEDs in the array may be configured to emit different spectrums (colors) of light by employing different phosphor compositions. Similarly, in an array of direct emitting LEDs (i.e., not wavelength converted by phosphors) all LEDs in the array may be configured to emit essentially the same spectrum of light, or the array may be a multicolor array comprising LEDs configured to emit different colors of light.

The individual LEDs or pcLEDs in an array may be individually operable (addressable) and/or may be operable as part of a group or subset of (e.g., adjacent) LEDs or pcLEDs in the array.

An array of LEDs or pcLEDs, or portions of such an array, may be formed as a segmented monolithic structure in which individual LEDs or pcLEDs are electrically isolated or partially electrically isolated from each other by trenches and/or insulating material, but the electrically isolated or partially electrically isolated segments remain physically connected to each other by other portions of the semiconductor structure. For example, in such a monolithic structure the active region and a first semiconductor layer of a first conductivity type (n or p) on one side of the active region may be segmented, and a second unsegmented semiconductor layer of the opposite conductivity type (p or n) positioned on the opposite side of the active region from the first semiconductor layer. The second semiconductor layer may then physically and electrically connect the segmented structures to each other on one side of the active region, with the segmented structures otherwise electrically isolated from each other and thus separately operable as individual LEDs.

An LED or pcLED array may therefore be or comprise a monolithic multicolor matrix of individually operable LED or pcLED light emitters. The LEDs or pcLEDs in the monolithic array may for example be microLEDs as described above.

A single individually operable LED or pcLED or a group of adjacent such LEDs or pcLEDs may correspond to a single pixel (picture element) in a display. For example, a group of three individually operable adjacent LEDs or pcLEDs comprising a red emitter, a blue emitter, and a green emitter may correspond to a single color-tunable pixel in a display.

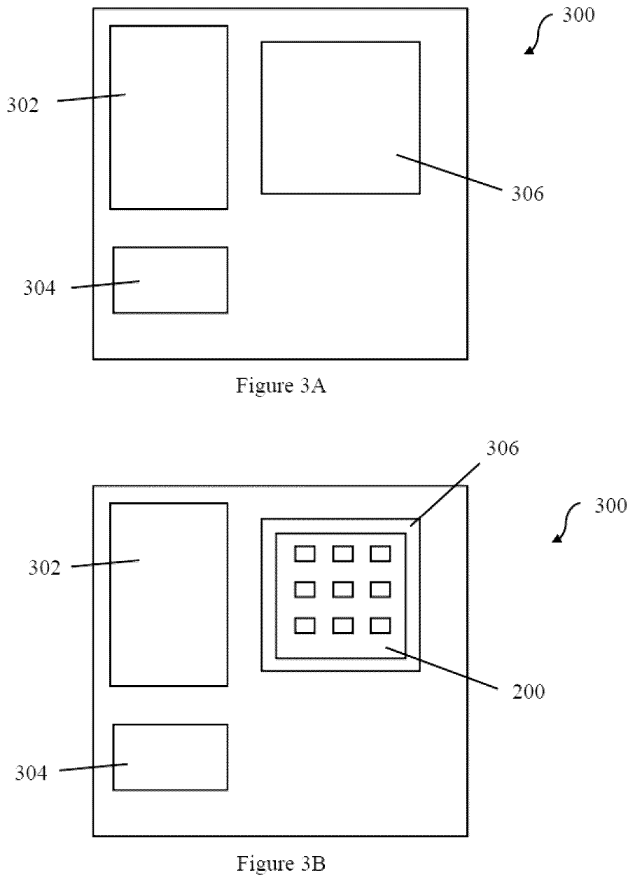

As shown in FIGS. 3A-3B, an LED or pcLED array 200 may for example be mounted on an electronics board 300 comprising a power and control module 302, a sensor module 304, and an attach region 306. Power and control module 302 may receive power and control signals from external sources and signals from sensor module 304, based on which power and control module 302 controls operation of the LEDs/pcLEDs. Sensor module 304 may receive signals from any suitable sensors, for example from temperature or light sensors. Alternatively, array 200 may be mounted on a separate board (not shown) from the power and control module and the sensor module.

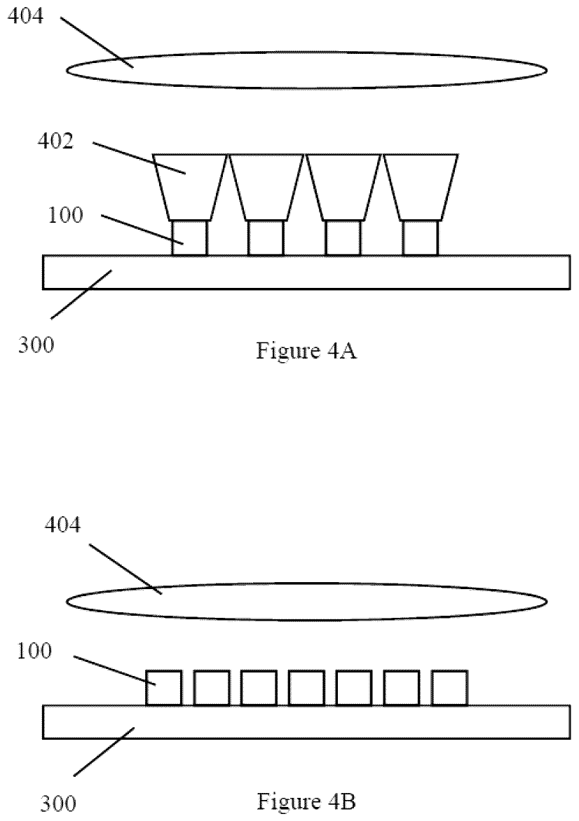

Individual LEDs or pcLEDs may optionally incorporate or be arranged in combination with a lens or other optical element located adjacent to or disposed on the LED or the phosphor layer of the pcLED. Such an optical element, not shown in the figures, may be referred to as a “primary optical element”. In addition, as shown in FIGS. 4A-4B an array 200 (for example, mounted on an electronics board 300) may be arranged in combination with secondary optical elements such as waveguides, lenses, or both for use in an intended application. In FIG. 4A, light emitted by pcLEDs 100 is collected by waveguides 402 and directed to projection lens 404. Projection lens 404 may be a Fresnel lens, for example. This arrangement may be suitable for use, for example, in automobile headlights. In FIG. 4B, light emitted by pcLEDs 100 is collected directly by projection lens 404 without use of intervening waveguides. This arrangement may be particularly suitable when LEDs or pcLEDs can be spaced sufficiently close to each other and may also be used in automobile headlights as well as in camera flash applications. A microLED display application may use similar optical arrangements to those depicted in FIGS. 4A-4B, for example.

In another example arrangement, a central block of LEDs or pcLEDs in an array may be associated with a single common (shared) optic, and edge LEDs or pcLEDs located in the array at the periphery of the central bloc are each associated with a corresponding individual optic.

Generally, any suitable arrangement of optical elements may be used in combination with the LED and pcLED arrays described herein, depending on the desired application.

LED and pcLED arrays as described herein may be useful for applications requiring or benefiting from fine-grained intensity, spatial, and temporal control of light distributions. These applications may include, but are not limited to, precise special patterning of emitted light from individual LEDs or pcLEDs or from groups (e.g., blocks) of LEDs or pcLEDs. Depending on the application, emitted light may be spectrally distinct, adaptive over time, and/or environmentally responsive. Such arrays may provide pre-programmed light distribution in various intensity, spatial, or temporal patterns. The emitted light may be based at least in part on received sensor data and may be used for optical wireless communications. Associated electronics and optics may be distinct at an individual LED/pcLED, group, or device level.

An array of independently operable LEDs or pcLEDs may be used in combination with a lens, lens system, or other optic or optical system (e.g., as described above) to provide illumination that is adaptable for a particular purpose. For example, in operation such an adaptive lighting system may provide illumination that varies by color and/or intensity across an illuminated scene or object and/or is aimed in a desired direction. Beam focus or steering of light emitted by the LED or pcLED array can be performed electronically by activating LEDs or pcLEDs in groups of varying size or in sequence, to permit dynamic adjustment of the beam shape and/or direction without moving optics or changing the focus of the lens in the lighting apparatus. A controller can be configured to receive data indicating locations and color characteristics of objects or persons in a scene and based on that information control LEDs or pcLEDs in an array to provide illumination adapted to the scene. Such data can be provided for example by an image sensor, or optical (e.g., laser scanning) or non-optical (e.g., millimeter radar) sensors. Such adaptive illumination is increasingly important for automotive (e.g, adaptive headlights), mobile device camera (e.g., adaptive flash), AR, VR, and MR applications such as those described below.

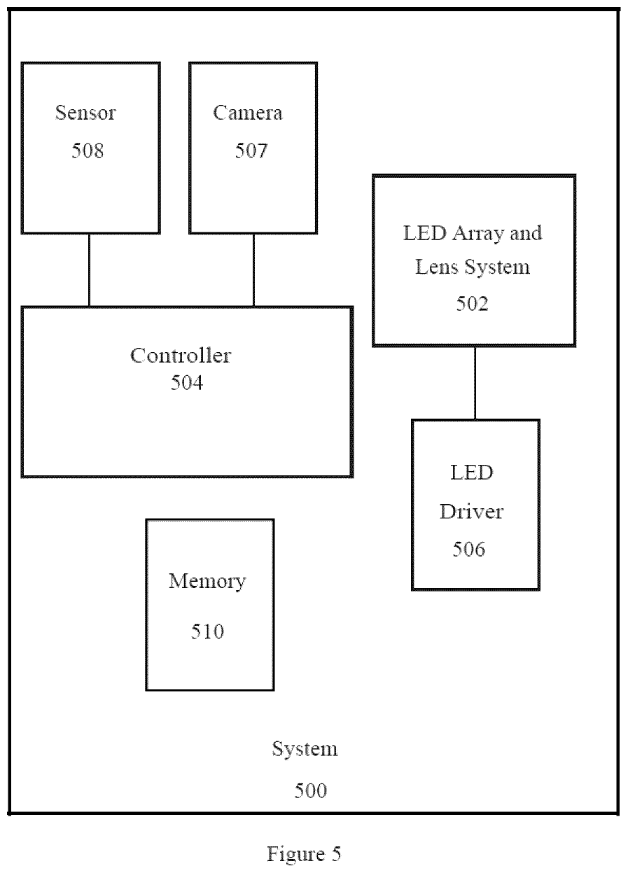

FIG. 5 schematically illustrates an example camera flash system 500 comprising an LED or pcLED array and an optical (e.g., lens) system 502, which may be or comprise an adaptive lighting system as described above in which LEDs or pcLEDs in the array may be individually operable or operable as groups. In operation of the camera flash system, illumination from some or all of the LEDs or pcLEDs in array and optical system 502 may be adjusted—deactivated, operated at full intensity, or operated at an intermediate intensity. The array may be a monolithic array, or comprise one or more monolithic arrays, as described above. The array may be a microLED array, as described above.

Flash system 500 also comprises an LED driver 506 that is controlled by a controller 504, such as a microprocessor. Controller 504 may also be coupled to a camera 507 and to sensors 508 and operate in accordance with instructions and profiles stored in memory 510. Camera 507 and LED or pcLED array and lens system 502 may be controlled by controller 504 to, for example, match the illumination provided by system 502 (i.e., the field of view of the illumination system) to the field of view of camera 507, or to otherwise adapt the illumination provided by system 502 to the scene viewed by the camera as described above. Sensors 508 may include, for example, positional sensors (e.g., a gyroscope and/or accelerometer) and/or other sensors that may be used to determine the position and orientation of system 500.

Analysis of certain automotive system optics suggests that a shaped surface luminance, where the center is peaked or with a gradient from one side to another side has the best system optics efficiency, indicated by the system optic figure of merit (FOM). There may be different optimal spatial luminance for high beam with total internal reflection (TIR) lens optical system versus low beam reflector optical systems. Regardless of if the beam is high or low, both systems may employ a multi-die package.

A multi-die package may provide shaped luminance. To accomplish this, several dies each with their own shaped luminance may be attached to a tile. These dies may not necessarily be segmented but may provide a smooth luminance with no strong discontinuity between different areas. Dies with shaped luminance have an area with a peak luminance and an area with less than peak luminance. For example, individual dies may each have a luminance gradient. In a multi-die package, the peak luminance of the dies may be aligned, e.g. on the same side of the tile, to provide a gradient for the luminance of the package as a whole. If possible, the peak luminance is aligned on the side of the package with less material: OSC, tile, electrical contact pad, etc. This configuration may offer the highest contrast and maximize the FOM gain.

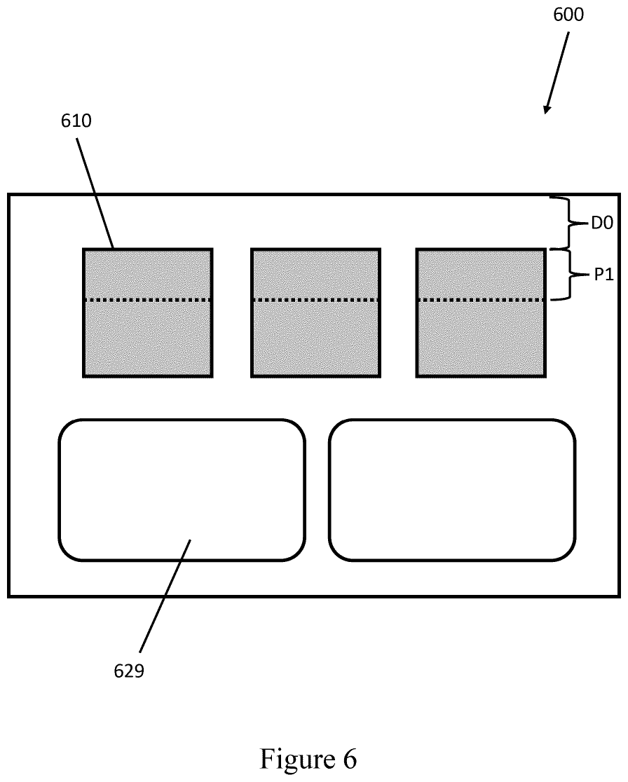

FIG. 6 shows a multi-die package with shaped luminance profile dies. For example, the package may have a 1×3 array of dies, that is, arranged in a single row with three columns. Various other arrangements are possible, such as X by Y arrays where X is 1 through 10 and Y is the same or different number of 1 through 10.

The package 600 includes multiple die 610 and at least one tile contact pad 629. In embodiments of the invention, package 600 includes three or more dies 610 and two tile contact pads 629. The dies 610 may be disposed adjacent to each other with gaps between die as low as possible in order to maximize the luminance. Likewise, the distance DO of the dies from the edge of the tile may be as small as possible for better contrast. The two tile contact pads 629 may be electrically connected to the die by Cu vias in case of ceramic tile and lead frame in case of FR4 tile. Since dies are connected in serial, one tile contact pad 629 is connected to the anode of 1st die and the other is connected to cathode of last die. In FIG. 6 it is shown that the two tile contact pads 629 are on top of the tile 640 (e.g., the substrate 640). However, the tile contact pads 629 may be on the bottom of the tile 640, and their areas in the plan view may overlap the dies 610 (from the opposite side of the tile 640 on which the dies 610 are disposed). In this case there may be electric vias through dielectric material of the tile 640 bridging the tile contact pads 629 and the dies 610.

The dies 610 may each individually have shaped luminance. Shaped luminance profile die is defined as a die where the luminance averaged over an area equal to at least 10% of the whole light emitting area deviates 20% or more of the mean luminance averaged over the whole light emitting area. This area may be the peak luminance area. For example, each die may have a gradient of luminance with an area of peak luminance and an area of lesser luminance. The gradient may be various types. One type of gradient is arranged so that the lowest luminance is on the four edges of the die, gradually increasing to the center where there is peak luminance. Another type of gradient is arranged from a first edge of the die to the opposite edge of the die, such that the luminance at the first edge is the peak luminance and the luminance at the opposite edge is the lowest luminance in the die, with the luminance from the first edge continually decreasing to the opposite edge. The area of peak luminance may have a length or width extending in a horizontal direction parallel with the upper edge of the dies 610 (the horizontal direction may extend along the length—the longest dimension—of the package 600, the horizontal direction being perpendicular to a vertical direction). These areas of peak luminance may include the upper edge of the dies 610 (closest to the top of the page of FIG. 6). In this setup, the dies may be arranged on the tile such that their edges of peak luminance are all horizontally aligned with each other to extend in the same direction, which means their edges of lowest luminance on the opposite side of the die 610 are aligned with each other as well. This provides a package 600 with shaped luminance that is brighter towards one edge than the other. In another arrangement the dies have their edges of lowest luminance aligned and adjacent to the upper edge of the package 600. However, these arrangements are not a requirement, and the dies may have their edges of peak luminance unaligned and facing in different directions from each other. For ease of understanding, the following description will assume the case where the dies 610 have their peak luminance aligned with each on the upper edge of the dies 610 in FIG. 6, unless otherwise noted.

The dies 610 on the tile may be electrically connected to each other in series. Electrical pads 620 may be used to connect the dies. These electrical pads 620 may comprise multiple layers, some of which are in direct contact with the dies and some of which are not. In embodiments of the invention, electrical pads 620 may comprise Under Bump Metallization (UBM) with a negative (“n”) or positive (“p”) polarity regions (nUBM and pUBM, respectively) both in direct contact with the dies 610, a tile top metallization layer in direct contact with the tile, and solder layers connecting the nUBM/pUBM with the tile top metallization layer. The nUBM and pUBM footprint on the die may have different areas, so that one is bigger than the other. The nUBM/pUBM may be square, rectangular, or other shape. It may have sharp corners or beveled or curved corners.

The asymmetric areas of the nUBM and pUBM may be because with dies of shaped, nonuniform surface luminance, a large electrical pad is required under the peak current area (e.g., the peak luminance area) to maximize heat dissipation to the tile and reduce thermal resistance (Rth).

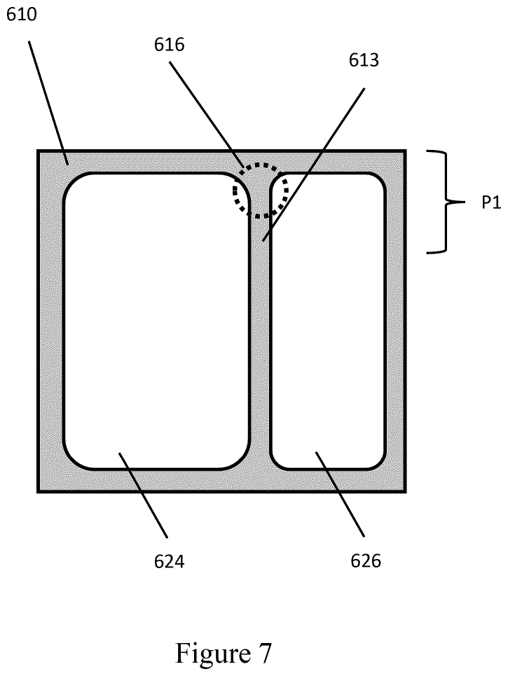

One possible arrangement of the nUBM 624 and pUBM 626 footprint on the die is shown in FIG. 7. As an example, the peak luminance of the die has a length that run parallel to the upper edge of die 610 (the edge which is closer to the upper edge of the page of FIG. 7). P1 denotes one possible peak luminance area, which may be smaller or larger depending on the particular luminance requirements. The peak luminance area may be a rectangular in shape with a length extending in the horizontal direction. This arrangement may be called a vertical arrangement, because the length of the nUBM and pUBM is perpendicular to length of the peak luminance extending along the upper edge of the die, is perpendicular to the length of the tile 610, and/or is perpendicular to the direction along which the dies 610 are arranged on the tile.

The nUBM 624 and pUBM 626 on a particular die 610 have a gap 613 in between them so that they are not in direct physical contact with each other. This gap is may be filled with silicone or air. In a vertical arrangement, the peak luminance running along or near the upper edge runs across the gap between the nUBM/pUBM. A hot spot 616 may appear in this gap below the peak luminance/current area, since the heat dissipation at the gap is not optimal.

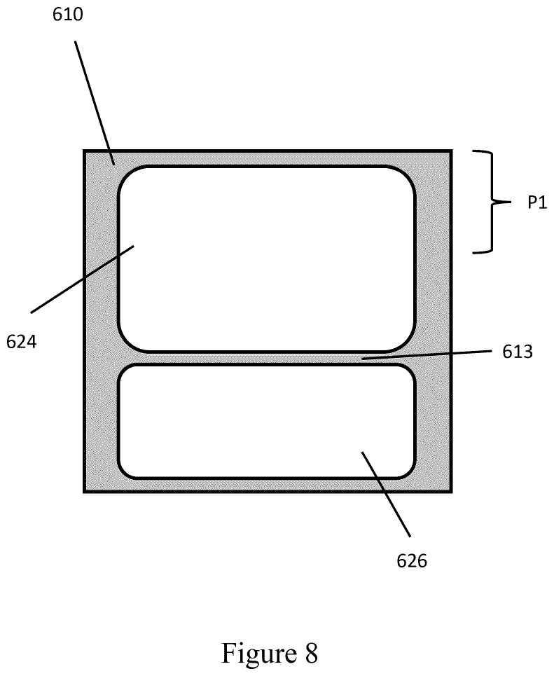

In order to prevent this hot spot, the nUBM 624 and pUBM 626 may be arranged in a horizontal arrangement. Embodiments of this invention preventing the hot spot is shown in FIG. 8. The length of nUBM/pUBM are parallel with the peak luminance extending along the upper edge or the direction of the upper edge, are perpendicular to the length of the tile 610, and/or are perpendicular to the direction along which the dies 610 are arranged on the tile. Here, nUBM 624 is shown as the larger of the two pads, but alternatively the larger pad shown in FIG. 8 could be pUBM instead with the smaller pad being nUBM. In other words, pUBM 626 and nUBM 624 can be swapped with each other in any descriptions of any embodiments of this invention as described in the figures or text below (while keeping the same area/dimensions of the depicted elements).

The peak luminance area P1 does not overlap with the smaller pad, pUBM 626 in this case, and only overlaps with the larger one of the pads, nUBM 624 in this case. (Overlap may mean when viewing the face of the plane of the package 600, the respective elements have some part of their areas intersecting; not overlapping means they have no part of their areas intersecting). For example, the nUBM may overlap with 80-100% of the peak luminance area P1, such as from 80-95%; this overlap by the nUBM may be over a contiguous, uninterrupted area. Likewise, the peak luminance area does not overlap with the gap 613 between nUBM and pUBM, so the hotspot is prevented. The gap 613 also does not overlap with the peak luminance area P1. Advantageously, there is now uniform or more uniform heat dissipation under the peak luminance area of the die.

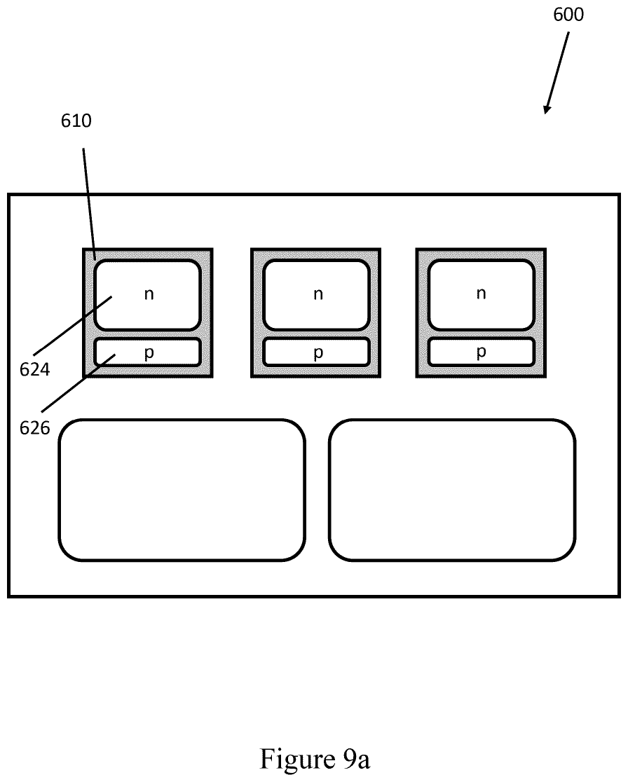

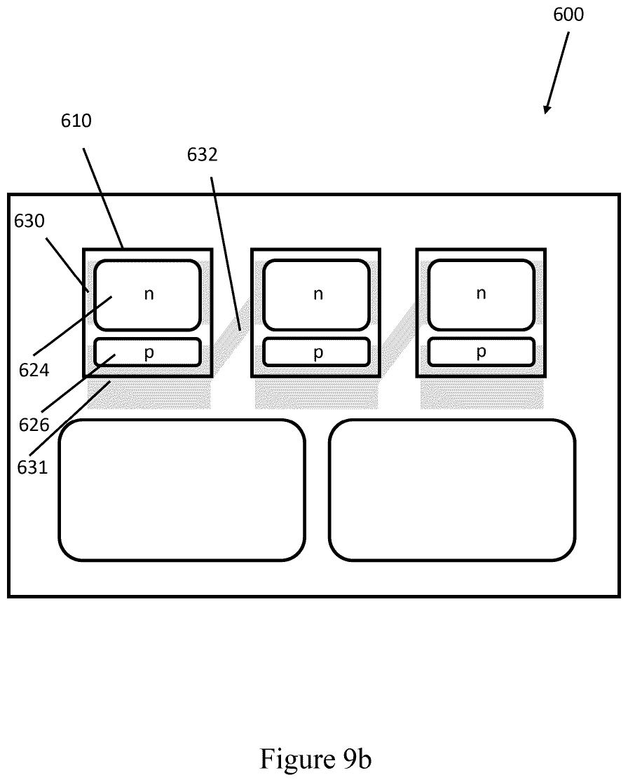

If the electrical pads 620 are arranged as in FIG. 7 on the tile, the n and p regions of the electrical pads of one die would be adjacent to the regions of electrical pads of opposite polarity a neighboring die. In embodiments of the invention as shown in FIGS. 8 and 9a which prevents the hot spot, taking into account not just the thermal but also the optical demands which wants to align the peak luminance on the same side of the package, regions of electrical pads 620 having the same polarity are now aligned along the horizontal direction (see FIG. 9A with the n and p regions). It is necessary to electrically connect these pads of opposite polarity, in order to serially connect the dies 610.

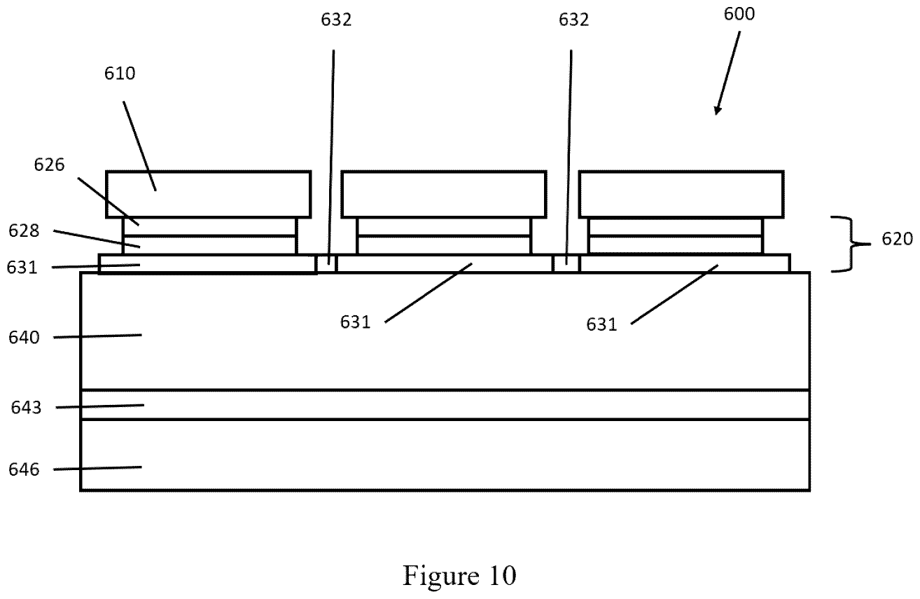

FIG. 10 shows FIG. 9 in cross section, when viewed from the lower edge of the package 600 in FIG. 9 (edge closest to the bottom of the page in FIG. 9). From this view, larger pad nUBM 624 is not visible, and only the smaller pad pUBM 626 is visible. Die 610 is disposed on pUBM 626 (and nUBM 624) and pUBM/nUBM is disposed on solder 628. Solder 628 is disposed in between and in direct physical contact with pUBM/nUBM and n tile top metallization layer 630 (not visible) and p tile top metallization layer 631. N/p tile top metallization layers 630/631 are in direct contact with the tile 640, and may share a polarity with the respective nUBM/pUBM under which they are disposed. The tile 640 may be a printed circuit board (PCB) or any other suitable substrate. Tile 640 is disposed on thermal interface and/or electrode layer 643, which is disposed on the heat sink 646.

The dies 610 are electrically connected to each other through the nUBM 624/pUBM 626, the solder 628, the n/p tile top metallization layer 630/631, and connections 632 between the tile top metallization layer 630. These connections may be done in various ways, including by soldering connections from a tile top metallization layer 630 under one die to a top tile top metallization layer 630 under a neighboring die. Because of the horizontal arrangement of the nUBM/pUBM and corresponding tile top metallization layer, this connection 632 may not be straight horizontal from one tile top metallization layer to another, but a diagonal metallization from the upper nUBM 624 to the lower pUBM 626 of the neighboring die (shown in FIG. 9b). This connection 632 may be diagonal in the sense that there both a nonzero horizontal and vertical component to its direction of extension, e.g., it may form an angle with respect to the upper edge of the die from which it extends from of 10-80 degrees, such as from 30-60 degrees, such as 45 degrees. The gap 613 between the nUBM 624 and the pUBM 626 may extend in a first horizontal direction. In that case, the diagonal connection 632 may extend vertically to intersect that first horizontal direction.

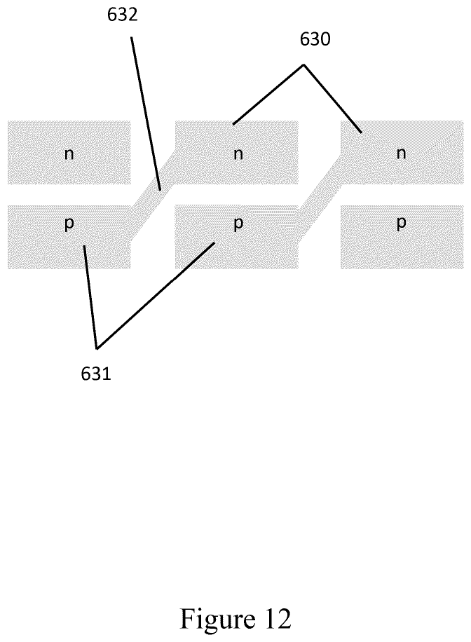

Connection 632 between n/p tile top metallization layers 630/631 is shown in FIG. 12 and FIG. 9b. FIG. 12 also shows the top down view or plan view of the tile top metallization layers 630 under each die. Like the nUBM 624/pUBM 626 layers, there are two tile tope metallization layers 630/631 of different polarity disposed under (i.e. partially or completely overlapping with) each die 610, as denoted by the “n” and “p” symbols. One or both of the tile top metallization layer 630/631 may extend past the die as shown in FIG. 9b (FIG. 9b shows the die 610 as transparent for ease of understanding). The n tile top metallization layer 630 of one die is electrically and physically connected to the p tile top metallization layer 631 of another die. The connection 632 between the two may be a diagonal metallization as mentioned above, i.e., from one tile top metallization layer to one of opposite polarity in a neighboring die. One way of defining the diagonal aspect is when the n tile top metallization layer 630 and p tile top metallization layer 631 of one die are horizontally aligned with, respectively, the n tile top metallization layer 630 and p tile top metallization layer 631 of another die, the connection extends from the upper n tile top metallization layer 630 of one die to the lower p tile top metallization layer 631 of the other die. Horizontal alignment may mean that the tile top metallization layer's upper edges are on the same horizontal line as each other and/or their lower edges are on the same horizontal line as each other, or simply that a horizontal line drawn through any part of them (such as one edge) intersects any region of both of them. The connection 632 may be disposed on the surface of the tile 640, or it may be embedded in the tile 640 so it is partially or completely under the tile top metallization layer. FIG. 10 shows the former embodiment.

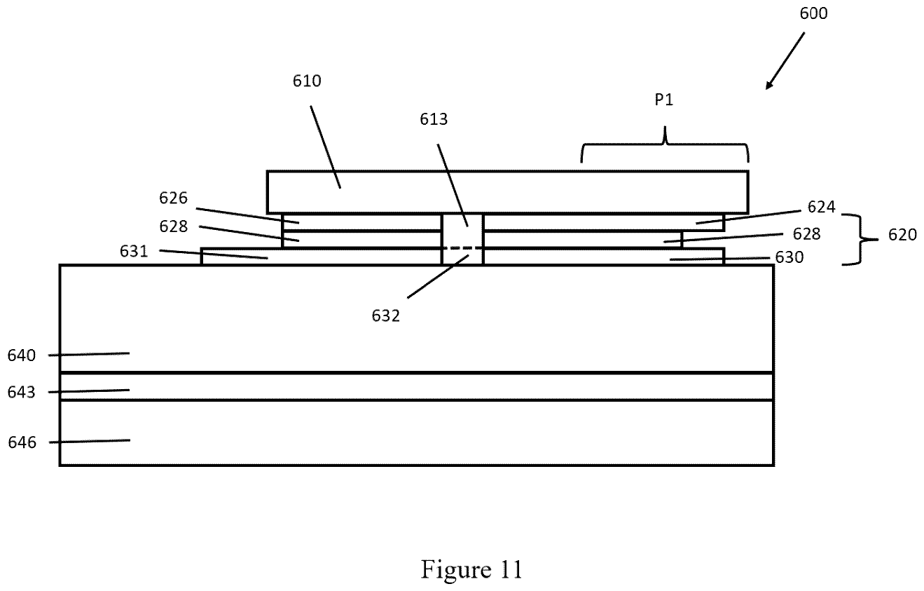

FIGS. 9b and 12 shows that the n/p tile tope metallization layers 630/631 of one die are spaced apart from each other without being in direct contact. For every outer die (die on the outer edges of the array), at least one of the n/p tile top metallization layers 630/631 is not physically connected with any metallization connection, while the other is. For every inner die (die with two neighboring dies) both of the n/p tile top metallization layers 630/631 are physically connected with a connection 632. FIG. 11 shows another cross section like FIG. 10, except viewed from the side of side edge of the package 600 in FIG. 9 (edge connecting the lower and upper edge of the package 600). Here, it is clear that the n/p tile metallization layer 630/631 of one die are electrically connected to each other through the solder 628, nUBM 624/pUBM 626, and the die 610.

The above described embodiments of the invention are advantageous in that they prevent hotspots from forming under areas of the die with peak luminance, since the gap 613 between the nUBM 624 and pUBM 626 is not disposed under that peak luminance area. As a result there is uniform heat dissipation under that area. But since the dies 610 need to be close to each other for luminance purposes, with this configuration there may a risk of solder paste overflow and short circuit creation when the diagonalization connection is soldered. With manufacturing tolerance to consider, the gap between dies may need to be increased. However, increasing spacing may reduce luminance of the full multi-die area and therefore reduce system optic FOM.

Embodiments of the present invention connect several dies with horizontal metal pads without the need to increase the spacing between dies or use solder with irregular shape after reflow. This method uses inverted electrical pad polarity between neighboring pads to alternate the placement of two die designs on the tile.

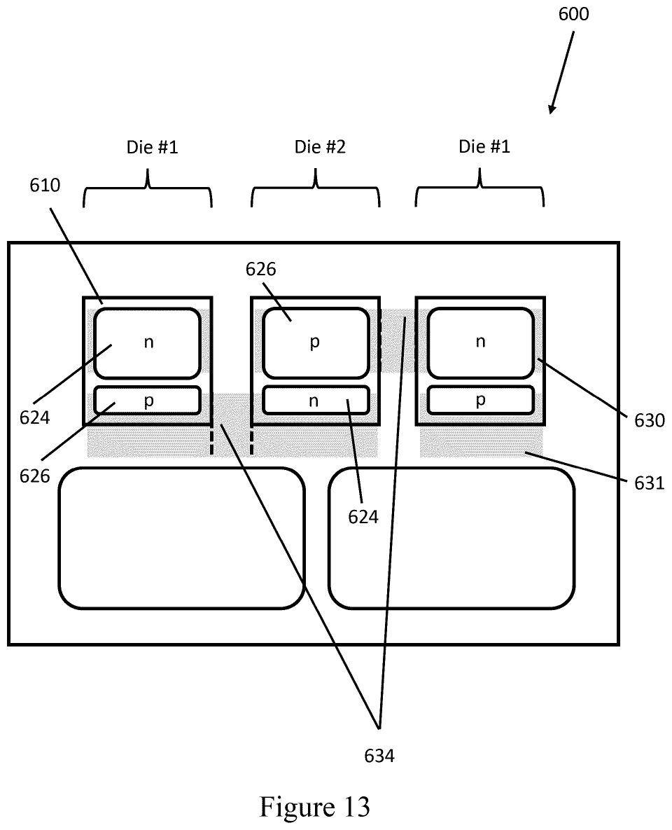

Electrical serial connection of the dies is obtained by alternating the placement of two different die design. These two die designs, die #1 and die #2, have the same orientation of asymmetrically sized electrical pads, different polarity for same sized pads. For example, die #1 has the largest pad for n contact and die #2 has the largest pad for p contact. FIG. 13 shows a view of the two die design. Practically, the inversion of metal pad polarity is obtained by modifying the opening of the dielectric layers, which includes insulation 665 described further below. Advantageously, the layout mask change is minimal as it concerns only the dielectric layers. Die #1 has a large horizontal n electrical pad (under the peak current area) and small horizontal p electrical pad. On the other hand, die #2 die has large horizontal p electrical pad (under the peak current area) and small horizontal n electrical pad. It is then possible to connect the die #1 and #2 in serial on the tile by alternating die #1 and die #2 without risk of short circuit. With this specific arrangement, each pad of a given die is aligned with pad of different polarity allowing easy serial connection on tile.

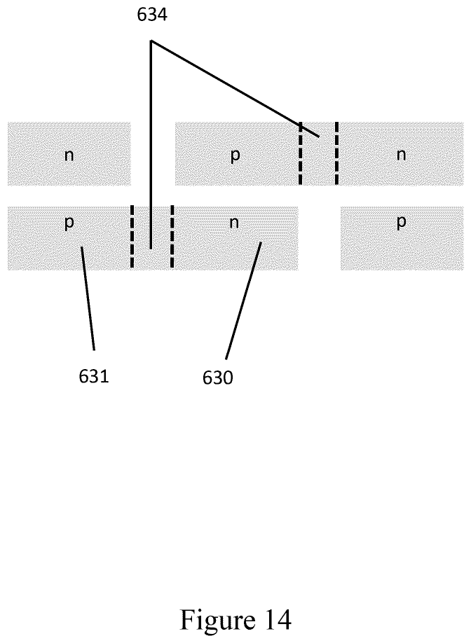

FIGS. 13 and 14 shows the alternating polarity design (die 610 is illustrated as transparent for informative purposes so that the tile top metallization layer 630 is visible). The n tile top metallization layer 630 of one die is electrically and physically connected to the p tile top metallization layer 631 of another die. The connection 634 connects the n and p tile top metallization layer 630 and 631 of two die. The connection 634 may have a same width (measured in the vertical direction) as the n and p tile top metallization layer 630 which it connects. The n and p tile top metallization layer 630 and 631 and the connection 634 may all be a continuous, unitary piece, and/or may be soldered together. The region of that unitary piece which is considered the n or p tile top metallization may be the region which overlaps with the die 610, and/or the regions which are not horizontally between neighboring dies 610 (but extend past the die without overlapping the die). Conversely, the region which is considered connection 634 may be that region which is horizontally between neighboring dies 610. Together, the connected n and p tile top metallization layer 630 and 631 may form a rectangle or square with the connection 634. In other words, the connection 634 is not diagonal, having a completely horizontal upper and lower edge that does not form any angle with respect to the upper or lower edge of the dies 610.

In embodiments of the invention illustrated in FIG. 13, outer dies in the die array of package 600 have at least two of the tile top metallization layers 630 that are not connected through connection 634 to a tile top metallization layer 630 of opposite polarity. This is because these tile top metallization layers are the beginning and ends of the serial connection powering the dies 610, so they themselves do not need to connect with another tile top metallization layer of another die. Rather, they may connect to the two tile contact pads 629, which is in turn connected to a drive circuit driving the dies. For example, for these outer dies, there may only be one connection 634 bridging their tile top metallization layers, so that one of the n tile top metallization 630 and p tile top metallization layer 631 has a connection 634 and the other lacks a connection 634, and is instead spaced apart from the connected n/p tile top metallization layer 630/631 of the same die and spaced apart from both of the n tile top metallization layer 630 and p tile top metallization layer 631 of the adjacent die. The at least two tile top metallization layers without a connection 634 in the die array may be of opposite polarity, and they may be disposed on opposite sides of the arrangement of dies 610. For example, as shown in FIGS. 13 and 14, the n tile top metallization layer 630 without a connection 634 is on the top left of the die array and the p tile top metallization layer 631 without a connection 634 is on the bottom left.

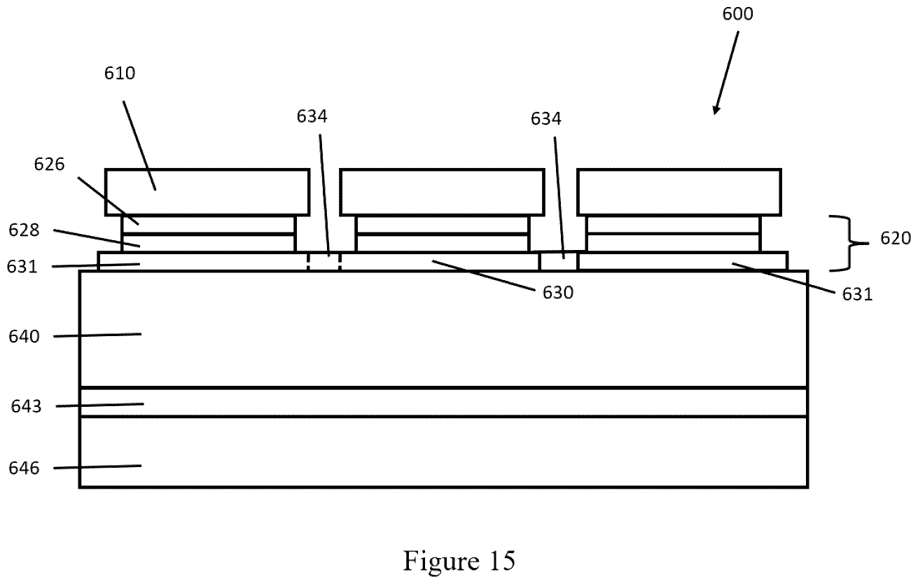

FIG. 15 shows a cross section of the package 600 depicted in FIG. 13 looking down the lower edge of the package. The connection 634 on the left side (demarcated by dashed lines) is closer to the viewer than the farther connection 634 on the right side (delineated by solid lines indicating the edges of the closer tile top metallization layers). FIG. 11 may also depict the package 600 seen down a side edge connecting the upper and lower edge of the package 600, except that the diagonal connection 632 depicted in dashed lines is not present in this embodiment.

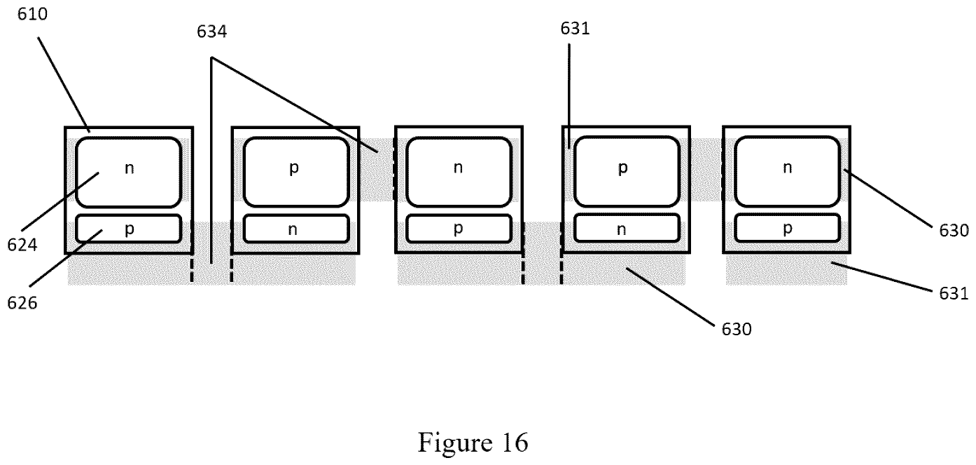

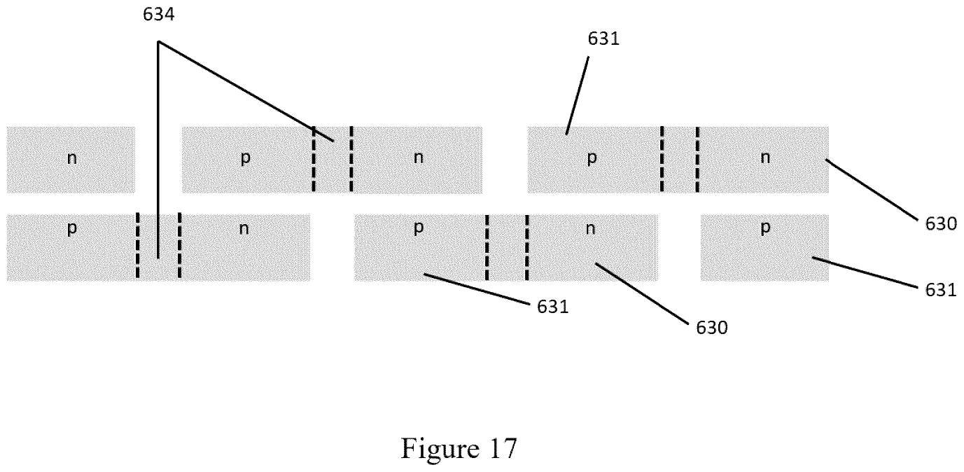

While FIGS. 13-15 show a package 600 with a 1×3 die array, this concept of alternating die designs may be generalized to larger or smaller 1×N arrays, where N is from 2 to 12, such as from 4 to 8. FIGS. 16 and 17 illustrates such generalization (a 1×5 die array in this case) with the depiction of the dies 610 and just the n/p tile top metallization layers 630/631, respectively.

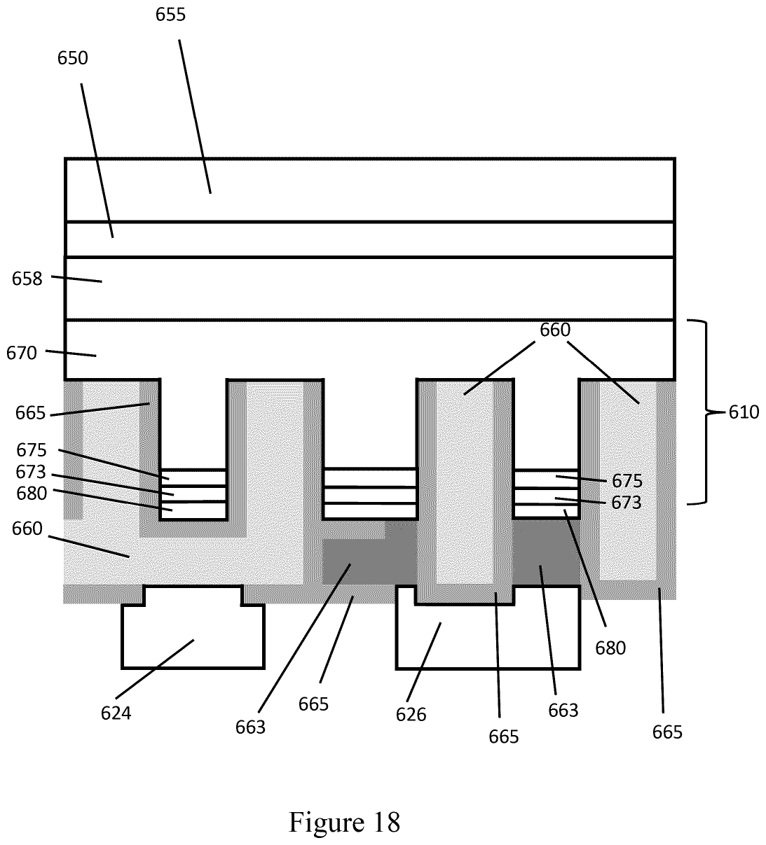

FIG. 18 shows the cross section of the die 610 with the connections of nUBM 624 and pUBM 626 in more detail. The die 610 comprises an epi layer with the nGaN layer 670, the quantum well 675, and the pGaN layer 673. The nUBM 624 is electrically connected to the nGaN layer 670 through the n bonding layer 660, which form nVias past the pGaN layer 673 that are physically spaced apart from the pGaN layer 673 by the insulation 665. The insulation 665 may be a dielectric material. The pUBM 626 is electrically connected to the pGaN layer by a p bonding layer 663. The p bonding layer 663 is in direct contact with both the pUBM 626 and either the pGaN layer 673 or a mirror layer 680 (e.g., made of silver) in electrical and/or direct physical contact with the pGaN layer 673. The p bonding layer 663 is physically spaced apart from the n bonding layer 660 by the insulation 665 so that they are not in direct physical contact. FIG. 15 shows the pUBM 626 as having the larger area than nUBM 624, but as noted above, this relation in size may be inverted as desired, as long as the larger of the pads covers the peak luminance area. Thus, the nUBM and n tile top metallization layer are electrically connected to the nGaN layer and the pUBM and p tile top metallization layer are electrically connected to the pGaN layer, and vice versa.

Disposed on the die 610 may be a substrate 658 (e.g., a sapphire platelet or undoped semiconductor material) bonded to a phosphor layer 655 by a glue layer 650. The die with adjustable light emitting area can be either VTF (vertical thin film or embedded contact vertical thin film), CSP (sapphire is still on the epi), or TFFC (Thin film flip chip). The die according to the invention can be built with a standard process. The specific step consists to get a paired die design with pad having inverting polarity. Inversion of pad polarity can be obtained simply by changing the layout of dielectric layers including insulation 655. All other layers may remain the same.

This disclosure is illustrative and not limiting. Further modifications will be apparent to one skilled in the art in light of this disclosure and are intended to fall within the scope of the appended claims.

1. A light emitting diode array, comprising:
a substrate;
a plurality of dies disposed on the substrate, each of the dies comprising a light emitting surface and configured to emit light in a peak luminance area of the light emitting surface having a greater average luminance than an average luminance of the light emitting surface, the dies comprising a first die and a second die adjacent to each other; and
a plurality of electrical pads disposed under a respective one of the dies, each of the electrical pads comprising:
a first under bump metallization (fUBM) having a first area and overlapping the peak luminance area of the respective one of the dies;
a second under bump metallization (sUBM) having a second area less than the first area; and
a gap spacing apart the fUBM and the sUBM that does not overlap the peak luminance area of the light emitting surface.

2. The light emitting diode array of claim 1, wherein the electrical pads each further comprise:
a first metallization layer disposed under the fUBM and arranged to have same polarity as the fUBM;
a second metallization layer disposed under the sUBM, the second metallization layer spaced apart from the first metallization layer and arranged to have opposite polarity as the first metallization layer; and
a connection connecting the first or second metallization layer of the first die to whichever of the first or second metallization layer of the second die has opposite polarity, the second die being adjacent to the first die.

3. The light emitting diode array of claim 2, wherein the first and second metallization layers are in direct contact with the substrate.

4. The light emitting diode array of claim 1, wherein the dies are arranged at least in a row extending in a horizontal direction perpendicular to a vertical direction, and the fUBM of adjacent ones of the dies are horizontally aligned with and have opposite polarities from each other, and the sUBM of adjacent ones of the dies are horizontally aligned with and have opposite polarities from each other.

5. The light emitting diode array of claim 4, wherein the electrical pads each further comprise:
a first metallization layer disposed under the fUBM and arranged to have same polarity as the fUBM;
a second metallization layer disposed under the sUBM, the second metallization layer spaced apart from the first metallization layer and arranged to have opposite polarity as the first metallization layer; and
a connection connecting the second metallization layer of the first die to the second metallization layer of the second die, the second die being adjacent to the first die; and
wherein the first metallization layer of adjacent ones of the dies are horizontally aligned with and have opposite polarities from each other, and the second metallization layer of adjacent ones of the dies are horizontally aligned with and have opposite polarities from each other.

6. The light emitting diode array of claim 2, wherein the electrical pads each further comprise a solder disposed between the fUBM and the first metallization layer.

7. The light emitting diode array of claim 2, wherein at least one of the first and second metallization layer extends beyond the die under which it is disposed.

8. The light emitting diode array of claim 2, wherein the connection is disposed between the first and second die without overlapping the first or second die.

9. The light emitting diode array of claim 5, wherein the connection has a same width in the vertical direction as respective widths in the vertical direction of the second metallization layers the connection connects.

10. The light emitting diode array of claim 4, wherein the first die is directly adjacent only to the second die, and the first metallization layer of the first die is spaced apart from the first metallization layer of the second die with a second gap between the first and second die.

11. The light emitting diode array of claim 1, wherein the peak luminance area of the die does not overlap with the sUBM.

12. The light emitting diode array of claim 1, wherein the dies are arranged in a 1 by X array, where X is from 3 to 5.

13. The light emitting diode array of claim 1, wherein the peak luminance area is equal in size to at least 10% of the light emitting surface, and the greater average luminance of the peak luminance area deviates 20% or more from an average luminance of the light emitting surface.

14. The light emitting diode array of claim 1, wherein the peak luminance area of the dies are horizontally aligned with one another.

15. The light emitting diode array of claim 1, wherein the fUBM of the first die is arranged to have negative polarity and the sUBM of the first die is arranged to have positive polarity.
